(19) United States
(12) Patent Application Publication
(10) Pub. No.: US 2013/0181360 A1
(43) Pub. Date: Jul. 18, 2013

(54) INTEGRATED CIRCUIT CONNECTIVITY USING FLEXIBLE CIRCUITRY

(71) Applicants: Namhoon Kim, Campbell, CA (US); Joong-Ho Kim, San Jose, CA (US); Paul Y. Wu, Saratoga, CA (US); Suresh Ramalingam, Fremont, CA (US)

(72) Inventors: Namhoon Kim, Campbell, CA (US); Joong-Ho Kim, San Jose, CA (US); Paul Y. Wu, Saratoga, CA (US); Suresh Ramalingam, Fremont, CA (US)

(73) Assignee: XILINX, INC., San Jose, CA (US)

(21) Appl. No.: 13/353,299

(22) Filed: Jan. 18, 2012

(51) Int. Cl. H01L 23/522; H01L 21/50

(52) U.S. Cl. 257/777; 438/121; 257/E23.142; 257/E21.499

(57) ABSTRACT

An integrated circuit (IC) structure can include an internal element and a flexible circuitry directly coupled to the internal element. The flexible circuitry can be configured to exchange signals between the internal element and a node external to the IC structure.

### FIELD OF THE INVENTION

One or more embodiments disclosed within this specification relate to integrated circuits (ICs). More particularly, one or more embodiments relate to establishing connections with an IC structure using flexible circuitry.

### BACKGROUND

Next generation integrated circuits (ICs) are expected to support data transmission rates that far exceed those attained in conventional IC architectures. For example, next generation ICs will likely need to support data transmission rates above approximately 25 Gbps. Disadvantages with current IC packaging technology, however, makes meeting this goal problematic if not highly improbable.

Communication channels formed using conventional IC packaging technologies suffer from a variety of disadvantages that can inhibit data transmission rates. One disadvantage is that communication channels that incorporate a package substrate and/or printed circuit board (PCB) elements typically suffer from high loss. Another disadvantage is that discontinuities may exist in the communication channel at or around solder bumps and/or via connections. These discontinuities can restrict bandwidth of the communication channel. These disadvantages can render a communication channel formed using a conventional IC architecture unsuitable for achieving the high data transmission rates noted.

### SUMMARY

One or more embodiments disclosed within this specification relate to integrated circuits (ICs) and, more particularly, to establishing connections with an IC structure using flexible circuitry.

An embodiment can include an IC structure including an internal element and a flexible circuitry directly coupled to the internal element. The flexible circuitry can be configured to exchange signals between the internal element and a node external to the IC structure.

Another embodiment can include a method of implementing an IC structure. The method can include coupling a first end of a flexible circuitry to an internal element of the IC structure and coupling a second end of the flexible circuitry to a node external to the IC structure. The flexible circuitry can be configured to exchange signals between the internal element and the node external to the IC structure.

Another embodiment can include a system. The system can include a first IC structure including an internal element. The system also can include a flexible circuitry having a first end configured to couple to the internal element of the first IC structure. The flexible circuitry can be configured to exchange signals between the internal element and a node external to the first IC structure.

### BRIEF DESCRIPTION OF THE DRAWINGS

FIG. 1 is a cross-sectional side view of an integrated circuit (IC) structure in accordance with an embodiment disclosed within this specification.

FIG. 2 is a cross-sectional side view of the IC structure of FIG. 1 in accordance with another embodiment disclosed within this specification.

FIG. 3 is a cross-sectional side view of the IC structure of FIG. 1 in accordance with another embodiment disclosed within this specification.

FIG. 4 is a cross-sectional side view of an IC structure in accordance with another embodiment disclosed within this specification.

FIG. 5 is a cross-sectional side view of the IC structure of FIG. 4 in accordance with another embodiment disclosed within this specification.

FIG. 6 is a cross-sectional side view of the IC structure of FIG. 4 in accordance with another embodiment disclosed within this specification.

FIG. 7 is a cross-sectional side view of the IC structure of FIG. 4 in accordance with another embodiment disclosed within this specification.

FIG. 8 is a cross-sectional side view of the IC structure of FIG. 4 in accordance with another embodiment disclosed within this specification.

FIG. 9 is a cross-sectional side view of the IC structure of FIG. 4 in accordance with another embodiment disclosed within this specification.

FIG. 10 is a perspective view of a cap configured for use with an IC structure in accordance with another embodiment disclosed within this specification.

FIG. 11 is a flow chart illustrating a method of implementing an IC structure in accordance with another embodiment disclosed within this specification.

### DETAILED DESCRIPTION OF THE DRAWINGS

While the specification concludes with claims defining features of one or more embodiments that are regarded as novel, it is believed that the one or more embodiments will be better understood from a consideration of the description in conjunction with the drawings. As required, one or more detailed embodiments are disclosed within this specification. It should be appreciated, however, that the one or more embodiments are merely exemplary. Therefore, specific structural and functional details disclosed within this specification are not to be interpreted as limiting, but merely as a basis for the claims and as a representative basis for teaching one skilled in the art to variously employ the one or more embodiments in virtually any appropriately detailed structure. Further, the terms and phrases used herein are not intended to be limiting, but rather to provide an understandable description of the one or more embodiments disclosed herein.

One or more embodiments disclosed within this specification relate to integrated circuits (ICs) and, more particularly, to establishing connections with an IC structure using flexible circuitry. In one aspect, a flexible circuitry can be used to couple an IC structure to one or more nodes of a circuit or system external to the IC structure itself. The flexible circuitry can couple to any of a variety of internal structural elements of the IC structure, thereby establishing a communication channel between the IC structure and the external node(s). By utilizing flexible circuitry, various IC structural elements that can inhibit data transfer rates can be avoided or bypassed.

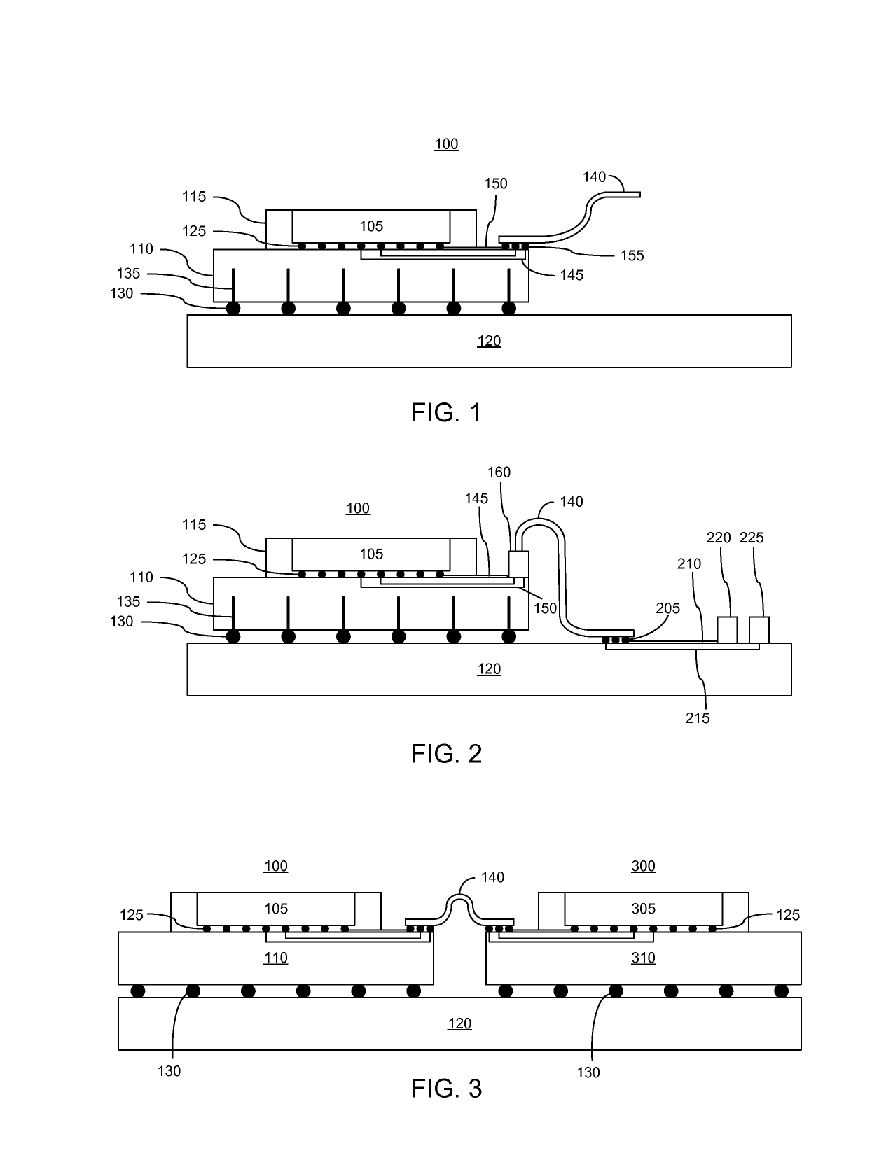

FIG. 1 is a cross-sectional side view of an IC structure 100 in accordance with an embodiment disclosed within this specification. As shown, IC structure 100 can include a die 105 coupled, e.g., mounted, on a substrate 110. Substrate 110 can be a package substrate used to mount or otherwise implement a die within IC packaging. Die 105 can be substantially covered or encompassed by a cap portion (cap) 115. As used within this specification, the “cap” portion can refer to a part of the packaging of an IC structure. The cap portion can be formed of a plastic or other material that typically includes an epoxy resin. The cap portion can cover one or more parts of an IC structure such as the die or dies. The cap portion typically is formed of a material intended to shield potentially light sensitive parts of the IC, e.g., the dies, from light, e.g., ultraviolet light, to prevent incorrect operation of the parts. Cap 115 also can be referred to as a “shield,” a “cover,” a “case,” a “portion” of IC packaging, or the like.

Die 105 can be implemented as any of a variety of different types of circuits. For example, die 105 can be implemented in the form of a processor, e.g., a microprocessor, an application specific IC (ASIC), a programmable IC, e.g., a field programmable gate array (FPGA), or the like. In any case, die 105 can include exclusively active circuit elements, exclusively passive circuit elements, and/or a combination of both active and passive circuit elements.

In one aspect, die 105 can be coupled to substrate 110 through a plurality of solder bumps 125. The use of solder bumps 125 to mount die 105 on a top surface of substrate 110 can serve to physically couple die 105 to substrate 110 and also to electrically couple die 105 to substrate 110. In an embodiment, solder bumps 125 can be implemented in the form of “micro-bumps,” e.g., as “fine pitch” bumps.

Although die 105 can be coupled to substrate 110 using solder bumps 125, a variety of other techniques can be used to couple die 105 to substrate 110. For example, bond wires or edge wires can be used to electrically and/or physically couple die 105 to substrate 110. In another example, an adhesive material can be used to physically couple die 105 to substrate 110. As such, the coupling of die 105 to substrate 110 via solder bumps 125, as illustrated within FIG. 1, is provided for purposes of illustration and is not intended to limit the one or more embodiments disclosed within this specification.

IC structure 100 can be coupled electrically and physically to a printed circuit board (PCB) 120. In one aspect, IC structure 100 can be coupled to PCB 120 through a plurality of solder bumps 130. Solder bumps 130 can be implemented in the form of flip-chip or controlled collapse chip connect (C4) type connections. For example, solder bumps 130 can be implemented as “coarse pitch” bumps. Coarse pitch solder bumps have a pitch that is coarser, e.g., larger, than that of a fine pitch solder bump.

In one aspect, solder bumps 130 can couple to vias 135. Each via 135 can couple to a signal within die 105 through one or more patterned metal layers (not shown) and one or more other vias configured to couple adjacent ones of the patterned metal layers. In general, one or more signals such as power, ground, and other data signals can be conveyed to and/or from die 105 through solder bumps 125 to vias 135, to solder bumps 130, and to conductors located within PCB 120. It should be appreciated, however, that one or more signals, e.g., high speed or other enumerated signals, can be routed to flexible circuitry 140 as opposed to propagating through vias 135 and/or solder bumps 130.

As shown, one or more signals from die 105 can be routed to flexible circuitry 140 via a conductive line 145 and/or a conductive line 150 in substrate 110 without passing through, or utilizing, vias 135 and/or solder bumps 130. Within the one or more embodiments disclosed within this specification, one or more signals can be routed to flexible circuitry 140. One or more other signals, e.g., data signals of lesser speed than those carried through flexible circuitry 140, power, ground, etc., can be routed through substrate 110 and, if or when applicable, an interposer, for example. Accordingly, flexible circuitry 140 can carry less than all signals, e.g., a subset of designated signals, whether inputs or outputs, for IC structure 100.

Conductive line 145 can be formed of one or more patterned metal layers and/or other vias configured to couple adjacent ones of the patterned metal layers available within substrate 110 to couple one or more solder bumps 125 to flexible circuitry 140. In another example, conductive line 150 can be formed on or in substrate 110 to couple one or more solder bumps 125 to flexible circuitry 140. In one example, conductive line 150 can be implemented as a micro-strip line and/or a strip-line.

In general, a micro-strip line refers to a type of conductor, e.g., an electrical transmission line, that can be fabricated on or as part of a printed circuit board, a package substrate, on-chip (as part of a die), or the like, and that can be used to convey microwave-frequency signals. A micro-strip line can refer to a conducting strip separated from a ground plane by a dielectric layer. A strip-line, by comparison, can be implemented as a conductor. More particularly, a strip-line can be formed using a flat strip of metal that is located between two parallel ground planes. The insulating material of the substrate can form a dielectric. The width of the strip-line, the thickness of the substrate, and the relative permittivity of the substrate determine the characteristic impedance of the strip-line. Like a micro-strip line, a strip-line can be formed as part of a printed circuit board, a package substrate, on-chip, or the like.

In one aspect, flexible circuitry 140 can be implemented as a plurality of conductors encapsulated in a thin dielectric film or other flexible dielectric material. In one example, flexible circuitry 140 can be implemented as a flexible printed circuit (FPC) or the like. In another example, flexible circuitry 140 can be implemented as a flexible, flat cable, or the like. Flexible circuitry 140, in some cases, is referred to as a “flex circuit” or “flex circuitry.”

Referring to the FPC example, flexible circuitry 140 can be implemented using photolithographic technology or by laminating thin copper strips between two layers of an encapsulating material such as PET or the like. These layers can be coated with an adhesive type of thermosetting that can be activated when the layers are laminated together. As known, one or more devices or components can be attached or included in flexible circuitry 140.

The various exemplary implementations of flexible circuitry 140 are provided for purposes of illustration only. As such, the examples are not intended to be limiting as to the nature or implementation of flexible circuitry 140 or the one or more embodiments disclosed within this specification. Any of a variety of flexibly circuitry implementations and/or flexible circuits can be used as long as the frequency requirements for the signals carried by the flexible circuits are met and the flexible circuitry can be coupled, e.g., electrically, to the various structures described within this specification. In this regard, flexible circuitry, in general, is capable of bending without breaking or causing a discontinuity or electrical open circuit in a conductor within the flexible circuitry.

Flexible circuitry 140 can be configured to propagate signals of varying frequency ranging from direct current, e.g., “DC” signals, such as power and/or ground to signals with data transmission rates of approximately 25 Gbps and higher. Thus, in one aspect, flexible circuitry 140 can be configured to propagate only power and/or ground signals, only data signals, only data signals with frequencies above a selected threshold, or a combination of DC, low frequency, and high frequency signals. When used to propagate high frequency signals, flexible circuitry 140 can provide reduced loss characteristics, e.g., reduced reflection loss and reduced insertion loss, than is attainable with other conventional IC packaging structures.

Flexible circuitry 140 is coupled, e.g., physically and electrically, to an internal element of IC structure 100. FIG. 1 illustrates an embodiment in which the internal element of IC structure 100 is substrate 110. Flexible circuitry 140, for example, can be physically and electrically coupled to conductive lines 145 and/or 150. FIG. 1 illustrates an embodiment in which flexible circuitry 140 is coupled to substrate 110 using solder bumps 155. Solder bumps 155 can be implemented in the form of micro-bumps, as C4 type bumps, or the like. In the example pictured in FIG. 1, the conductors from within flexible circuitry 140 can be exposed and available for coupling to substrate 110. As noted, the conductors of flexible circuitry 140 can be bonded to conductive lines 145 and/or 150 using solder bumps 155.

For example, a technique referred to as ultrasonic bonding can be used to couple conductors of flexible circuitry 140 with substrate 110. Ultrasonic bonding or welding can be used for bond assembly. Ultrasonic bonding refers to a “cold” joining process that can join metals, plastics, and textiles. Ultrasonic bonding directs high-frequency vibrations at two components that are clamped together. The high-frequency vibrations create a rapid build-up of heat at the bonding interfaces that produces a bond in a minimal amount of time without any significant melting of the base materials. Ultrasonic bonding results in less thermal stress to the components involved than other bonding techniques.

In another example, anisotropic conductive film (ACF) bonding can be used. ACF refers to a tape or an epoxy system used make electrical and mechanical connections between electronics and substrates. ACF bonding, for example, can be used for fine pitch soldering, e.g., for pitches less than approximately 200 μm. The bonding techniques disclosed herein are provided for purposes of illustration and, as such, are not intended as limitations of the one or more embodiments disclosed herein.

FIG. 2 is a cross-sectional side view of IC structure 100 of FIG. 1 in accordance with another embodiment disclosed within this specification. FIG. 2 illustrates an embodiment in which flexible circuitry 140 is coupled to IC structure 100 using a mechanical connector 160. Mechanical connector 160, for example, can be electrically and physically coupled to substrate 110 and can be configured to receive a complementary mechanical connector coupled to an end of flexible circuitry 140. For example, mechanical connector 160 can be a socket in which a complementary portion, e.g., a male connector, coupled to flexible circuitry 140 can be inserted to physically and electrically couple IC 100 to conductive lines 145 and/or 150. Alternatively, mechanical connector 160 can be formed to engage a socket or other shape of complementary connector coupled to the end of flexible circuitry 140. It should be appreciated that while the connectors are described as being “mechanical,” the term mechanical is intended to refer to the manner in which the connectors engage with one another and can release. The mechanical connectors, for example, still establish an electrical connection when engaged.

As pictured, flexible circuitry 140 can be coupled to an external node, e.g., a node external to IC structure 100, located on PCB 120 through one or more solder bumps 205. Solder bumps 205 can be any of a variety of solder bump types, e.g., micro-bumps, C4 bumps, or the like. As shown, PCB 120 can include conductive lines 210 and/or 215. For example, conductive line 210 can be implemented as a micro-strip line and conductive line 215 can be implemented as a strip-line.

In order to couple to signals carried within flexible circuitry 140, a connector 220 can be coupled to PCB 120. Connector 220, for example, can electrically couple to one or more conductive lines such as conductive line 210. PCB 120 also can be coupled to a connector 225. Connector 225, for example, can electrically couple to one or more of conductive lines such as conductive line 215. Alternatively, both types of conductor lines 205 and 215 can couple to a single connector, e.g., connector 220 or connector 225.

FIG. 3 is a cross-sectional side view of IC structure 100 of FIG. 1 in accordance with another embodiment disclosed within this specification. As shown IC structure 100 can be coupled to another IC structure 300 using flexible circuitry 140. For purposes of illustration, particular elements of IC structure 100 and IC structure 300 such as vias within the substrates, for example, have been omitted. Further, some reference numbers have been omitted to more clearly illustrate various aspects of the example pictured in FIG. 3.

Continuing, IC structure 300 can be implemented substantially similar, if not the same as, IC structure 100. IC structure 300, for example, can include a die 305 physically and electrically coupled to a substrate 310 via solder bumps 125. Substrate 310 can be physically and electrically coupled to PCB 120 through solder bumps 130. While PCB 120 can include one or more conductive lines therein that can be used to couple one or more solder bumps 130 beneath IC structure 100 to one or more solder bumps 130 beneath IC structure 300, one or more signals can be directly exchanged between IC structure 100 and IC structure 300 through flexible circuitry 140. Thus, flexible circuitry 140 can couple IC structure 100 to a node external thereto, e.g., a node located in IC structure 300.

By using flexible circuitry 140 to couple substrate 110 of IC structure 100 with substrate 310 of IC structure 300, signals routed through flexible circuitry 140 avoid various structures such as vias, solder bumps 130, metal traces and/or signal lines within PCB 120. Appreciably, the vias and solder bumps 130 that are avoided are bypassed in both IC structure 100 and in IC structure 300.

Solder bumps of the variety discussed within this specification often suffer from high losses and can include discontinuities that are problematic for achieving high data rates. For example, flexible circuitry 140 can be implemented using a low loss dielectric material. Flexible circuitry 140 can be implemented with dielectric loss tangents of approximately one-fourth that of comparable PCBs. Further, flexible circuitry 140 can be manufactured without the discontinuities that can characterize conventional IC package connections, e.g., vias and solder bumps.

Use of flexible circuitry 140 also allows increased input/output (I/O) density in that additional signals can be input and/or output for a given IC structure using a flexible circuitry despite little or no availability in the substrate to accommodate further inputs or outputs. For example, more signals, for example, can be output through substrate 110 and/or substrate 310 since the area typically required to output the data signals that now pass through flexible circuitry 140 is no longer needed. In another example, additional power and/or ground pins can be included in IC structure 100 (and IC structure 300, for example) that result in improved power distribution network (PDN)/simultaneous switching noise (SSN). In addition, more expensive, low loss materials for implementing the PCB and/or package may no longer be needed.

In another embodiment, IC structure 100 can include a mechanical connector as illustrated with reference to FIG. 2. Similarly, IC structure 300 can include a mechanical connector. In such an embodiment, each end of flexible circuitry 140 can terminate in a mechanical connector that can cooperatively engage the mechanical connector on IC structure 100 and the mechanical connector on IC structure 300. In this manner, flexible circuitry 140 can be inserted into each respective connector to physically and electrically couple to the IC structure and also be removed from each respective connector.

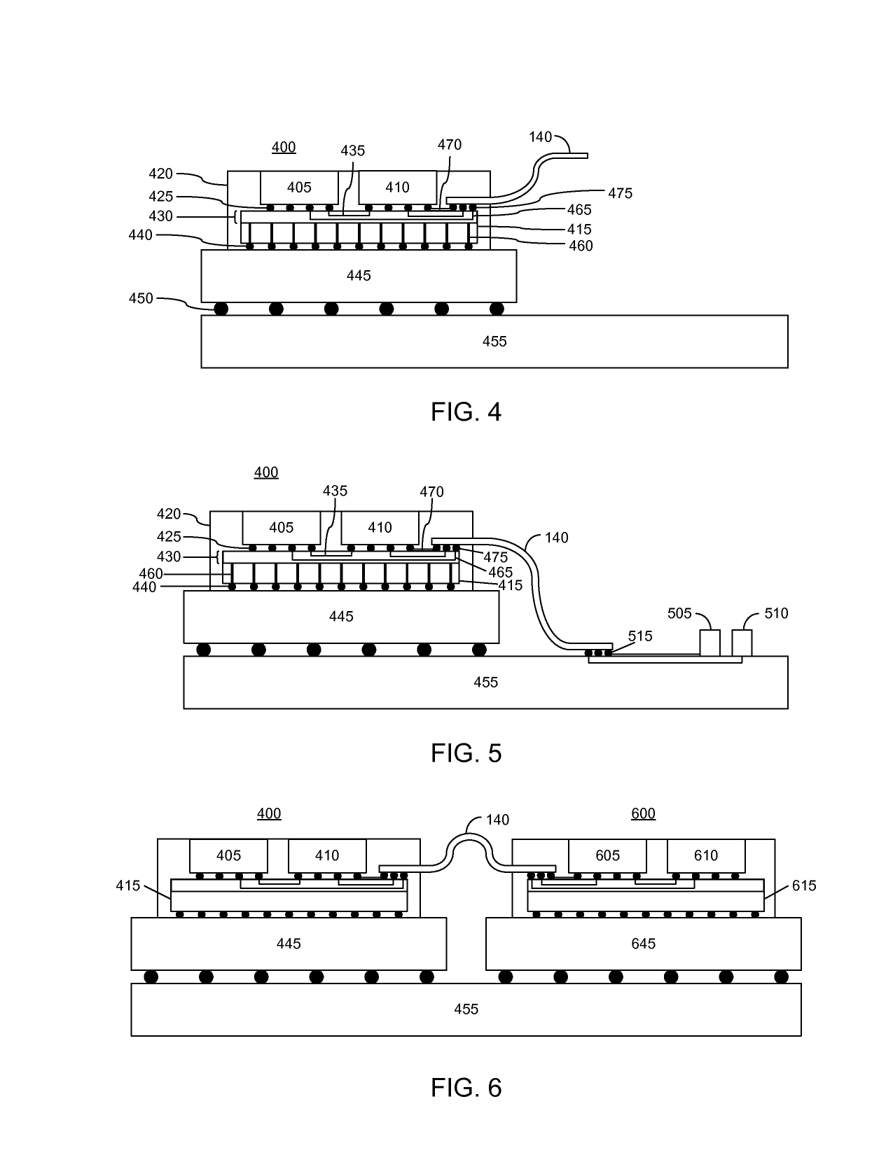

FIG. 4 is a cross-sectional side view of an IC structure 400 in accordance with another embodiment disclosed within this specification. IC structure 400 can include one or more dies such as dies 405 and 410 coupled, e.g., mounted, on an interposer 415. As shown, a cap 420 can cover dies 405 and 410. FIG. 4 illustrates an embodiment in which interposer 415 is the internal element of IC structure 400 to which flexible circuitry 140 is directly coupled.

Interposer 415 can be a die having a planar surface on which each of dies 405-410 can be horizontally stacked. Although IC structure 400 is shown with two or more horizontally stacked dies, e.g., side-by-side on a same surface of interposer 415, IC structure 400 also can be implemented with two or more dies being stacked vertically on top of interposer 410. For example, die 410 can be stacked on top of die 405. In still another embodiment, interposer 415 can be used as an intermediate layer between two vertically stacked dies.

Interposer 415 can provide a common mounting surface and electrical coupling point for dies 405 and 410 of a multi-die IC structure as shown. Interposer 415 can serve as an intermediate layer for interconnect routing between dies 405 and 410 or as a ground or power plane for IC structure 400. Interposer 415 can be implemented with a silicon wafer substrate, whether doped or un-doped with an N-type and/or a P-type impurity. The manufacturing of interposer 415 can include one or more additional process steps that allow the deposition of one or more layer(s) of metal interconnect. These metal interconnect layers can include aluminum, gold, copper, nickel, various silicides, and/or the like.

Interposer 415 can be manufactured using one or more additional process steps that allow the deposition of one or more dielectric or insulating layer(s) such as, for example, silicon dioxide. In general, interposer 415 can be implemented as a passive die in that interposer 415 can include no active circuit elements. In another aspect, however, interposer 415 can be manufactured using one or more additional process steps that allow the creation of active circuit elements such as, for example, transistor devices and/or diode devices. As noted, interposer 415 is, in general, a die and can be characterized by the presence of one or more through-silicon vias (TSVs) and/or the inclusion of inter-die wires as will be described in greater detail within this specification.

Implementation of interposer 415, and the various other interposers within this specification, as silicon interposers is provided for purposes of illustration only. Other types of interposers and corresponding structures within the interposers can be used. For example, interposers formed of organic materials, glass, or the like can be used. In this regard, other structures such as through-glass vias (TGVs) can be included in the case of a glass interposer. Accordingly, the various structures and materials disclosed within this specification are provided for purposes of illustration and, as such, are not intended as limitations of the one or more embodiments disclosed herein.

Each of dies 405 and 410 can be physically and electrically coupled to interposer 415 via solder bumps 425. Through solder bumps 425, for example, interposer 415 is electrically and physically coupled to die 405 and to die 410. In one aspect, solder bumps 425 can be implemented in the form of “micro-bumps.” Although dies 405 and 410 are shown coupled to interposer 415 through solder bumps 425, dies 405 and 410 can be coupled to interposer 415 using any of a variety of techniques. For example, bond wires or edge wires can be used to physically and electrically couple dies 405 and 410 to interposer 415. In another example, an adhesive material can be used to physically couple dies 405 and 410 to interposer 415. As such, the coupling of dies 405 and 410 to interposer 415 via solder bumps 425, as illustrated within FIG. 4, is provided for purposes of illustration and is not intended to limit the one or more embodiments disclosed within this specification.

Interconnect material within interposer 415 can be used to form inter-die wires that can pass inter-die signals between dies 405 and 410. A region labeled 430 of interposer 415 can include one or more conductive, e.g., patterned metal, layers forming wires or interconnects. For example, interconnect 435 can be formed using one or more of the patterned metal layers of region 430. Accordingly, interconnect 435 can represent an inter-die wire that can couple a solder bump 425 beneath die 405 with a solder bump 425 beneath die 410, thereby coupling die 405 to die 410 and allowing the exchange of inter-die signals between dies 405 and 410.

In addition, interposer 415 can be implemented with multiple conductive layers that can be coupled together with vias (not shown). In that case, interconnect 435 can be implemented within two or more conductive layers coupled together using vias within interposer 415. The use of multiple conductive layers to implement interconnects, e.g., inter-die wires, within interposer 415 allows a greater number of signals to be routed and more complex routing of signals to be achieved within interposer 415.

Solder bumps 440 can be used to electrically couple interposer 415 to a substrate 445. Substrate 445 can be implemented substantially similar to substrate 120 of FIGS. 1-3. As such, substrate 445 can include vias (not shown) that couple to solder bumps 450. Solder bumps 450 can couple substrate 445 with PCB 455. PCB 455 can be implemented substantially the same as PCB 120 of FIGS. 1-3. In an embodiment, solder bumps 440 and/or 450 can be implemented in the form of C4 bumps. It should be appreciated that the various structures illustrated in the figures, e.g., solder bumps 425, 440, and 450, are provided for purposes of illustration and, as such, are not drawn to scale.

TSVs 460 within interposer 415 can be implemented by drilling or etching an opening into interposer 415 that extends from a first planar surface, i.e., the surface to which solder bumps 425 are coupled, through to a second planar surface, i.e., the surface to which solder bumps 440 are coupled. Conductive material then can be deposited within the openings to form TSVs 460. Examples of conductive material that can be used to form TSVs 460 can include, but are not limited to, aluminum, gold, copper, nickel, various silicides, and/or the like. In another example, TSVs 460 can traverse substantially through interposer 415 to couple solder bumps 440 with one or more conductive layers of region 430 as are used to form interconnect 435. Interconnect 435 and one or more conventional vias then can couple TSVs 460 to solder bumps 425.

Die 405 and/or die 410 of IC 400 can be implemented in the form of an ASIC, a microprocessor, a programmable IC, or the like. For example, one or both of dies 405 and/or 410 can include dedicated circuitry. Dedicated circuitry can include one or more portions of circuitry that can be largely fixed. Some of the dedicated circuitry, however, can be parameterized to implement an operational mode that can be selected from a plurality of different operational modes, for example, based upon register settings. The phrase “dedicated circuitry,” however, refers to circuitry that is “hardwired,” “fixed,” or substantially unchanging. As such, dedicated circuitry is not considered “programmable.”

One or both of dies 405 and/or 410 can be implemented as a die that can be programmed to implement one or more different circuit designs, e.g., as a programmable IC. A programmable IC such as an FPGA, for example, can implement different physical circuitry, where each different physical circuitry is defined by the circuit design loaded into the die (FPGA). In this regard, the circuitry of die 405 and/or die 410 can be considered programmable, unlike dedicated circuitry.

As pictured in FIG. 4, flexible circuitry 140 can be physically and electrically coupled to interposer 415. Though shown to be coupled to interposer 415 using solder bumps 475, in another aspect, flexible circuitry 140 can be coupled to interposer 415 using a mechanical connector as previously described. Unlike FIG. 2, however, the mechanical connector can be coupled to interposer 415 as opposed to the substrate, e.g., substrate 445. Flexible circuitry 140 can be coupled to interposer 415 using any of the various techniques already described within this specification.

Either one or both of dies 405 and/or 410 can be electrically coupled to flexible circuitry 140, e.g., to propagate signals, through interconnect lines, e.g., interconnect 465, formed within region 430 of interposer 415 using the patterned conductive layers included therein. In another aspect, one or both of dies 405 and/or 410 can be electrically coupled to flexible circuitry 140 using conductive lines 470. Conductive lines 470 can be implemented in the form of micro-strip lines and/or strip-lines as previously described.

FIG. 5 is a cross-sectional side view of IC structure 400 of FIG. 4 in accordance with another embodiment disclosed within this specification. As shown, a first end of flexible circuitry 140 is coupled to interposer 415. A second end of flexible circuitry 140 is coupled to a node external to IC structure 400 located on PCB 455 using solder balls 515 as previously described. Conductive lines implemented within PCB 455 can couple flexible circuitry 140 to one or more mechanical connectors such as mechanical connector 505 and mechanical connector 510.

It should be appreciated that in another aspect, rather than physically and electrically coupling flexible circuitry 140 to PCB 455 as shown, the second end of flexible circuitry 140 can be configured to include a connector. The connector can be complementary to either one or both of mechanical connectors 505 and 510. Accordingly, flexible circuitry 140 can be plugged into either one or both of mechanical connectors 505 and/or 510 and unplugged when so desired. It should be appreciated that the various mechanical connectors described within this specification allow flexible circuitry 140, when equipped with a suitable mechanical connector, to be plugged into, e.g., engaged, into another mechanical connector located on a substrate, a PCB, or an interposer, subsequently removed, or unplugged, from the mechanical connector as desired without requiring more permanent means of coupling such as bonding or soldering.

FIG. 6 is a cross-sectional side view of IC structure 400 of FIG. 4 in accordance with another embodiment disclosed within this specification. As shown IC structure 400 can be coupled to another IC structure 600 using flexible circuitry 140. For purposes of illustration, particular elements of the IC structures 400 and 600 such as vias within the substrates, for example, have been omitted. Further, some reference numbers have been omitted to more clearly illustrate various aspects of the embodiment pictured in FIG. 6.

In any case, IC structure 600 can be implemented substantially similar, if not the same as, IC structure 400. IC structure 600, for example, can include dies 605 and 610 that are physically and electrically coupled to an interposer 615. Interposer 615 can be physically and electrically coupled to a substrate 645. Substrate 645 can be physically and electrically coupled to PCB 455. While PCB 455 can include one or more conductive lines therein that can be used to couple one or more solder bumps beneath substrate 445 to one or more solder bumps beneath substrate 645, one or more signals can be directly exchanged between IC structure 400 and IC structure 600 through flexible circuitry 140. As such, flexible circuitry 140 couples IC structure 400 to a node external thereto, e.g., a node within IC structure 600.

By using flexible circuitry 140 to couple interposer 415 of IC structure 400 with interposer 615 of IC structure 600, various structures such as vias, TSVs, solder bumps, and/or conductive lines can be avoided or circumvented. Appreciably, the vias and solder bumps that are avoided are bypassed in both IC structure 400 and in IC structure 600.

As noted, the use of flexible circuitry 140 allows increased I/O density. Additional power and/or ground pins also can be included in IC structure 400 (and IC structure 600, for example) that result in improved PDN/SSN. In addition, more expensive, low loss materials for implementing the PCB and/or packaging may no longer be needed.

In another embodiment, IC structure 400 can include a mechanical connector coupled to interposer 415 as described with reference to FIG. 5. IC structure 600, similarly can include a mechanical connector. In such an embodiment, each end of flexible circuitry 140 can terminate in a mechanical connector that can cooperatively engage the mechanical connector on IC structure 400 and the mechanical connector on IC structure 600. In this manner, flexible circuitry 140 can be inserted into each respective mechanical connector to physically and electrically couple to the IC and also be removed from each mechanical connector.

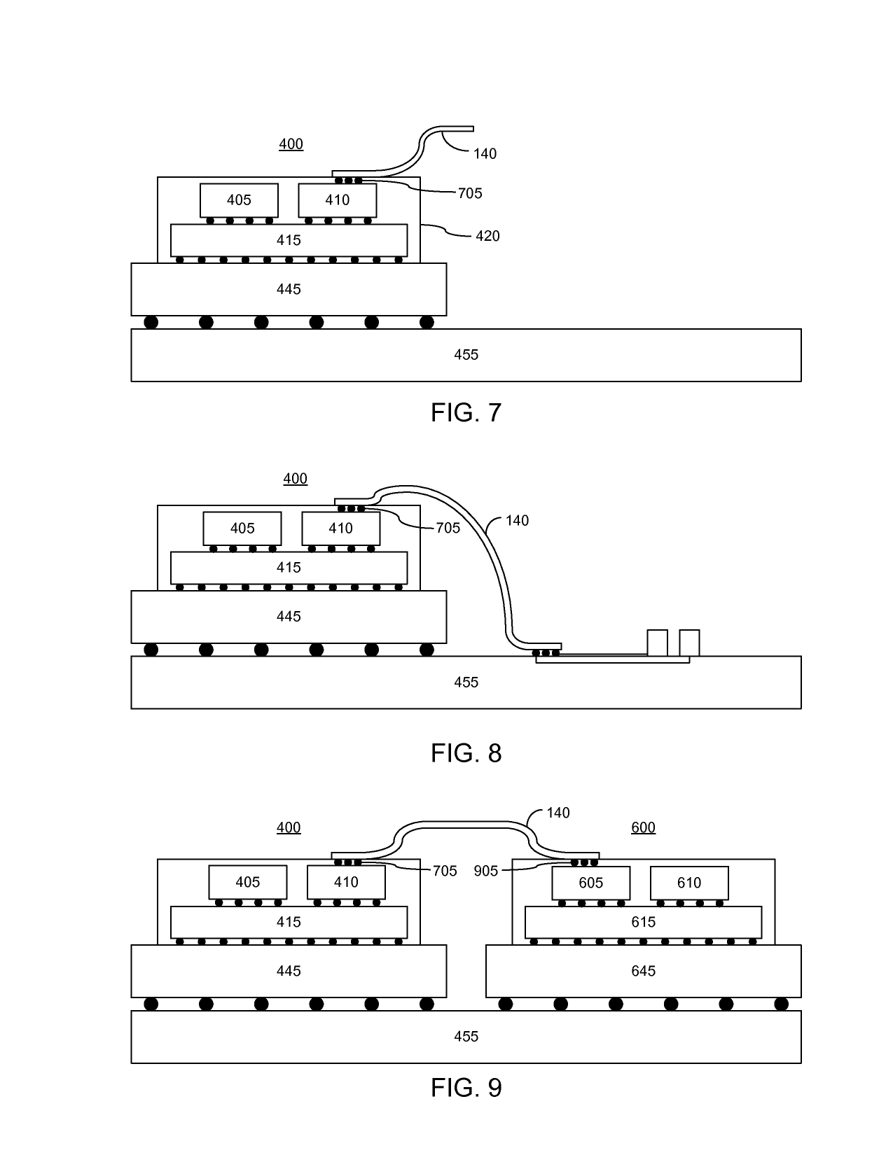

FIG. 7 is a cross-sectional side view of IC structure 400 of FIG. 4 in accordance with another embodiment disclosed within this specification. FIG. 7 illustrates an embodiment in which the internal element of IC structure 400 to which flexible circuitry 140 is directly coupled is the die. As shown, flexible circuitry 140 is coupled to die 410 as opposed to interposer 415. Flexible circuitry 140 can couple to a top surface of die 410 via one or more solder bumps 705. In one aspect, solder bumps 705 can be implemented as micro-bumps. As shown, flexible circuitry 140 can couple to die 410 via an opening in a top portion of cap 420.

It should be appreciated that since dies 405 and 410 can communicate via one or more inter-die signals exchanged within interposer 415, that one or both of dies 405 and/or 410 can communicate with a node external to IC structure 400 through flexible circuitry 140. In another embodiment, flexible circuitry 140 can be configured to split into two legs. A first leg can couple to a top surface of die 405. A second leg can couple to a top surface of die 410. The two legs can join into a single leg that can couple to one or more nodes external to IC structure 400. Still, it should be appreciated that each of dies 405 and 410 can be coupled to a different flexible circuitry thereby allowing die 405 to couple to one or more nodes external to IC structure 400 and die 410 to couple to one or more different nodes external to IC structure 400.

The nodes referred to as “external” in reference to connection points of one end or portion of flexible circuitry 140 are considered external to the particular IC structure to which the other end or portion of flexible circuitry 140 couples. For example, a node that is external to an IC structure can refer to a node that is not located on the same die (or any of the same dies in the case of a multi-die IC), not located on the same interposer, and/or not located on the same substrate of the IC structure. An external node can refer to, for example, a different IC or IC structure, a point or node located on a PCB as illustrated within this specification, or the like.

FIG. 8 is a cross-sectional side view of IC structure 400 of FIG. 4 in accordance with another embodiment disclosed within this specification. As shown, flexible circuitry 140 is coupled to die 410 as opposed to interposer 415. Flexible circuitry 140 can couple to a top surface of die 410 as described with reference to FIG. 7 through one or more solder bumps 705. FIG. 8 illustrates an example in which flexible circuitry 140 couples to an external node located on PCB 455 through one or more solder bumps as previously described within this specification.

FIG. 9 is a cross-sectional side view of IC structure 400 of FIG. 4 in accordance with another embodiment disclosed within this specification. As shown IC structure 400 can be coupled to IC structure 600 using flexible circuitry 140. As shown, flexible circuitry 140 can couple to a top surface of die 410 via solder bumps 705 to a node external to IC structure 400, e.g., a top surface of die 605 via solder bumps 905. While PCB 455 can include one or more signal lines therein that can be used to couple one or more solder bumps beneath substrate 445 to one or more solder bumps beneath substrate 645, one or more signals can be directly exchanged between IC structure 400 and IC structure 600 through flexible circuitry 140.

By using flexible circuitry 140 to couple die 410 with die 605 directly, various IC structures such as vias, TSVs, solder bumps, conductive lines can be avoided. Appreciably, the vias and solder bumps that are avoided are bypassed in both IC structure 400 and in IC structure 600.

It should be appreciated that while dies 410 and 605 are shown to be coupled directly, other configurations can be implemented. For example, flexible circuitry 140 can couple both dies 405 and 410 at one end, e.g., using two legs, with die 605, die 610, or both dies 605 and 610 at the other end. In another example, a first flexible circuitry can couple a first die of IC structure 400 to a first die of IC structure 600 and a second flexible circuitry can couple a second die of IC structure 400 to a second die of IC structure 600. Various combinations of the aforementioned configurations also can be implemented.

The examples illustrated with reference to FIGS. 7-9 are illustrated using multiple die configurations. It should be appreciated, however, flexible circuitry as described can be coupled directly to a die of an IC structure as illustrated with reference to FIGS. 1-3. As such, the one or more embodiments disclosed within this specification are not intended to be limited to coupling a flexible circuitry to a die or dies of a multi-die IC structure.

The various examples of dies that can be included within the IC structures described with reference to FIGS. 1-9 have been provided for purposes of illustration only. As such, the one or more embodiments are not intended to be limited to the examples provided. Further examples of dies can include memories, controllers, etc. It should be appreciated also that various combinations of the different dies provided can be included and used in the multi-die IC examples provided.

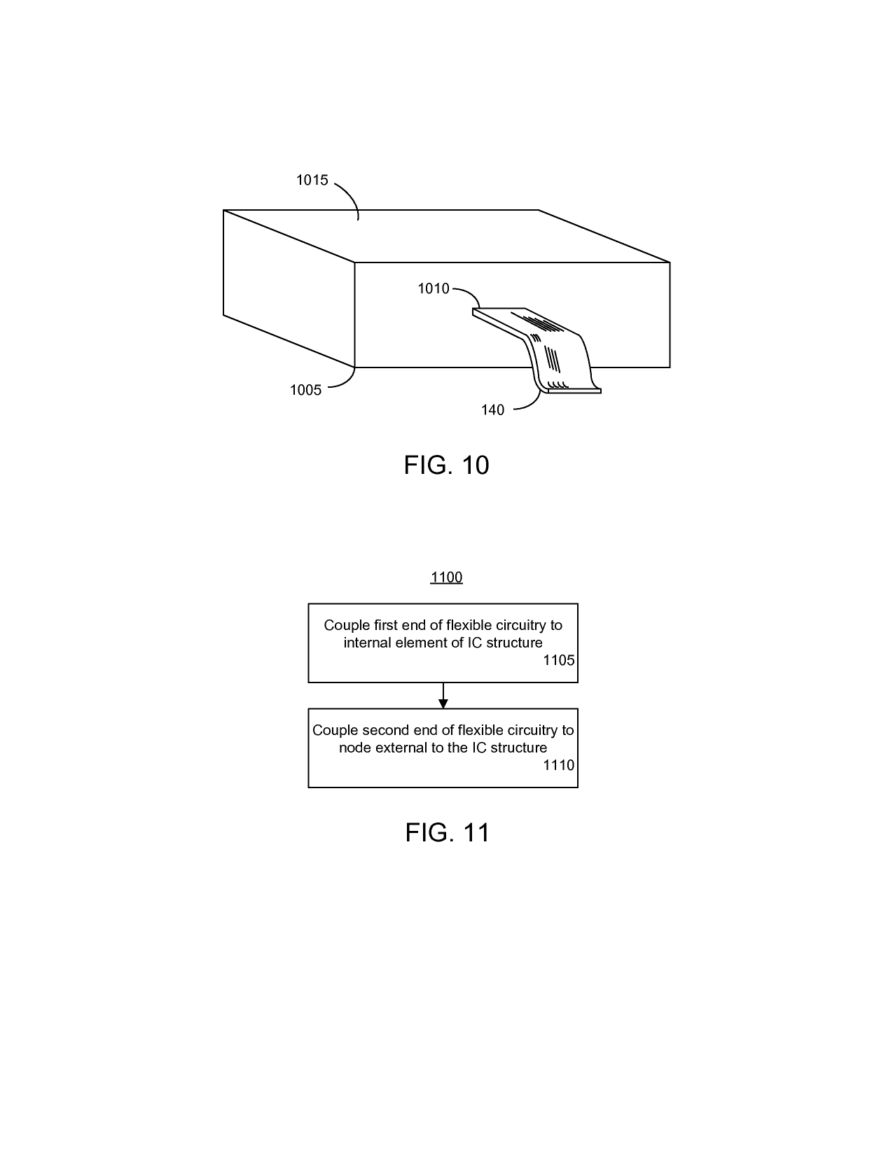

FIG. 10 is a perspective view of a cap 1005 configured for use with an IC structure in accordance with another embodiment disclosed within this specification. Cap 1005 is an example of the cap described within this specification with reference to FIGS. 1-9. In one aspect, cap 1005 can be a molded cap and can be configured to cover a die or one or more dies and an interposer, when applicable in a multi-die configuration.

In general, cap 1005 can be mounted to a top surface of a substrate, e.g., the same surface upon which either an interposer or a die is mounted. Cap 1005 can include an opening 1010, e.g., a slit, through which flexible circuitry 140 can pass. In this manner, flexible circuitry 140 can couple to an internal structure of the IC such as a die or an interposer as described within this specification. While opening 1010 is illustrated on a side of cap 1005, it should be appreciated that opening 1010 can be located on a top surface 1015 of cap 1005 or on another side as may be required and depending upon how flexible circuitry 140 is coupled, e.g., attached, to an attachment point on an internal element of the IC structure for which cap 1005 is used.

For example, while cap 420 in FIGS. 7-9 is shown to have an opening in a top portion, cap 1005 can be implemented with a height that leaves space between the bottom surface of the top of cap 1005 and the die located beneath. Accordingly, cap 1005 can be implemented so that flexible circuitry 140 can pass through the space between the top of die 410 and the bottom surface of the top of cap 1005 and pass through opening 1010.

FIG. 11 is a flow chart illustrating a method 1100 of implementing an IC structure in accordance with another embodiment disclosed within this specification. Method 1100 can begin in step 1105, where a first end of a flexible circuitry can be coupled to an internal element of an IC structure. As noted, the internal element can be one or more dies, a substrate, or an interposer. In step 1110, a second end of the flexible circuitry can be coupled to a node external to the IC structure. For example, the second end of the flexible circuitry can be coupled to a PCB, another IC structure, an internal element of another IC structure, e.g., an interposer, or the like.

For purposes of explanation, specific nomenclature is set forth to provide a thorough understanding of the various inventive concepts disclosed herein. The terminology used herein, however, is for the purpose of describing particular embodiments only and is not intended to be limiting. For example, reference throughout this specification to “one embodiment,” “an embodiment,” “another embodiment,” or similar language means that a particular feature, structure, or characteristic described in connection with the embodiment is included in at least one embodiment disclosed within this specification. Thus, appearances of the phrases “in one embodiment,” “in an embodiment,” “another embodiment,” and similar language throughout this specification may, but do not necessarily, all refer to the same embodiment.

The terms “a” and “an,” as used herein, are defined as one or more than one. The term “plurality,” as used herein, is defined as two or more than two. The term “another,” as used herein, is defined as at least a second or more. The term “coupled,” as used herein, is defined as connected, whether directly without any intervening elements or indirectly with one or more intervening elements, unless otherwise indicated. Two elements also can be coupled mechanically, electrically, or communicatively linked through a communication channel, pathway, network, or system.

The term “and/or” as used herein refers to and encompasses any and all possible combinations of one or more of the associated listed items. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof. It will also be understood that, the terms “first,” “second,” etc. may be used herein to reference various elements and to distinguish one element from another. The use of the terms “first,” “second,” etc. is not intended to imply an ordering of the referenced elements unless the context indicates otherwise.

The term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

Within this specification, the same reference characters are used to refer to terminals, signal lines, wires, and their corresponding signals. In this regard, the terms “signal,” “wire,” “connection,” “terminal,” and “pin” may be used interchangeably, from time-to-time, within this specification. It also should be appreciated that the terms “signal,” “wire,” or the like can represent one or more signals, e.g., the conveyance of a single bit through a single wire or the conveyance of multiple parallel bits through multiple parallel wires. Further, each wire or signal may represent bi-directional communication between two, or more, components connected by a signal or wire as the case may be.

The corresponding structures, materials, acts, and equivalents of all means or step plus function elements in the claims below are intended to include any structure, material, or act for performing the function in combination with other claimed elements as specifically claimed. The description of the one or more embodiments disclosed has been presented for purposes of illustration and is not intended to be exhaustive or limited to the form disclosed. The one or more embodiments disclosed within this specification can be embodied in other forms without departing from the spirit or essential attributes thereof. Accordingly, reference should be made to the following claims, rather than to the foregoing specification, as indicating the scope of the one or more embodiments.

What is claimed is:

1. An integrated circuit (IC) structure comprising:
an internal element; and
a flexible circuitry directly coupled to the internal element;
wherein the flexible circuitry is configured to exchange signals between the internal element and a node external to the IC structure.

2. The IC structure of claim 1, wherein the internal element is a die.

3. The IC structure of claim 1, further comprising:
a die;
wherein the internal element is a substrate; and
wherein the die is mounted on the substrate.

4. The IC structure of claim 3, further comprising:
a first mechanical connector coupled to the substrate; and
a second mechanical connector coupled to the flexible circuitry;
wherein the first and the second mechanical connectors are configured to cooperatively engage with one another and to disengage from one another.

5. The IC structure of claim 1, further comprising:
a cap substantially covering the internal element;
wherein the cap comprises an opening through which the flexible circuitry is configured to pass through.

6. The IC structure of claim 1, further comprising:
a die;
wherein the internal element is an interposer; and
wherein the die is mounted on the interposer.

7. The IC structure of claim 6, further comprising:
a first mechanical connector coupled to the interposer; and
a second mechanical connector coupled to the flexible circuitry;
wherein the first and the second mechanical connectors are configured to cooperatively engage with one another and to disengage from one another.

8. A method implementing an integrated circuit (IC) structure, the method comprising:
coupling a first end of a flexible circuitry to an internal element of the IC structure; and
coupling a second end of the flexible circuitry to a node external to the IC structure;
wherein the flexible circuitry is configured to exchange signals between the internal element and the node external to the IC structure.

9. The method of claim 8, wherein the internal element is a die of the IC structure.

10. The method of claim 8, wherein the internal element is an interposer of the IC structure.

11. The method of claim 8, wherein the internal element is a substrate of the IC structure.

12. A system comprising:
a first integrated circuit (IC) structure comprising an internal element; and
a flexible circuitry comprising a first end configured to couple to the internal element of the first IC structure;
wherein the flexible circuitry is configured to exchange signals between the internal element and a node external to the first IC structure.

13. The system of claim 12, further comprising:
a first mechanical connector coupled to the internal element; and
a second mechanical connector coupled to the flexible circuitry;
wherein the first and second mechanical connectors are configured to cooperatively engage with one another and to disengage from one another.

14. The system of claim 12, wherein the internal element is a die of the IC structure.

15. The system of claim 12, wherein the internal element is an interposer; and
wherein the first IC structure further comprises a die mounted on the interposer.

16. The system of claim 12, wherein the internal element is a substrate; and
wherein the first IC structure further comprises a die mounted on the substrate.

17. The system of claim 12, further comprising:
a printed circuit board configured to couple to the flexible circuitry.

18. The system of claim 17, wherein the flexible circuitry comprises a second end configured to couple to the printed circuit board through a mechanical connector.

19. The system of claim 12, further comprising:
a second IC structure comprising an internal element;
wherein the flexible circuitry comprises a second end configured to couple to the internal element of the second IC structure.

20. The system of claim 12, further comprising:
a printed circuit board; and
a second IC structure comprising an internal element;
wherein the first IC structure and the second IC structure are coupled to the printed circuit board; and
wherein the flexible circuitry comprises a second end configured to couple to the internal element of the second IC structure.
